(19) United States
(12) Patent Application Publication
(10) Pub. No.: US 2004/0246035 A1
(43) Pub. Date: Dec. 9, 2004

(54) Semiconductor integrated circuit

(75) Inventors: Koji Karatani, Osaka (JP); Gen Fukatsu, Osaka (JP); Akimitsu Shimamura, Osaka (JP)

Correspondence Address: McDERMOTT, WILL & EMERY, 600 13th Street, N.W., Washington, DC, 20005-3096, US

(73) Assignee: MATSUSHITA ELECTRIC INDUSTRIAL CO., LTD.

(21) Appl. No.: 10/857,026

(22) Filed: Jun. 1, 2004

(30) Foreign Application Priority Data
Jun. 6, 2003 (JP) P2003-161954

(51) Int. Cl. H03K 5/01

(52) U.S. Cl. 327/165

(57) ABSTRACT

Of synchronous circuit cells such as flip-flops, some are of blocked type and others remain unblocked. In a semiconductor integrated circuit according to the present invention, a clock generating circuit is independently provided for each of a plurality of the unblocked synchronous circuit cells for a clock input thereto, in order to control clock skews and achieve a lower power consumption. The clock generating circuit is independently connected to each of a plurality of functional blocks comprising a plurality of the blocked synchronous circuit cells for the clock input thereto.

### BACKGROUND OF THE INVENTION

The present invention relates to a semiconductor integrated circuit with clock generating circuits provided therein, more particularly to a technology of controlling clock skews. The clock skews are time lags occurred in the arrival timings of a plurality of clocks.

Generally in the semiconductor integrated circuit, clock signals used for synchronization are distributed from the clock generating circuits to respective synchronous circuit cells (such as flip-flop).

The conventional technology, in order to control the skews of the distributed clock signals, adopts such means as interposing delay adjustment cells, buffers and the like, or equalizing wiring lengths so that wiring delays can be constant.

However, the semiconductor integrated circuits in larger sizes and of higher speeds are now available, which necessitates the distribution of the clock signals of higher clock frequencies to thousands or tens of thousands of synchronous circuit cells. Further, because of the higher integration of the semiconductor integrated circuit, a larger variability in the manufacturing process is being increasingly generated. Because of these problems, the smaller the clock cycle is, the more difficult it is to control the clock skews.

Moreover, the clock signals are constantly toggled at the time of normal operation, which results in a larger power consumption in a clock series where the wirings are extensively spread.

### SUMMARY OF THE INVENTION

Therefore, a main object of the present invention is to provide a semiconductor integrated circuit capable of controlling clock skews resulting from wiring delays and further achieving a lower power consumption.

Other objects, features, and advantages of the present invention will become clear from the following description.

A first semiconductor integrated circuit according to the present invention comprises a clock generating circuit for each synchronous circuit cell incorporated therein. A typical example of such synchronous circuit cells is a flip-flop.

According to such a configuration, it becomes unnecessary to distribute clock signals because the clock generating circuit is independently provided for each synchronous circuit cell. More specifically, clock-series wirings required for distributing the clock signals are no longer necessary. This better controls the clock skews caused by the wiring delays in the wiring distribution.

A second semiconductor integrated circuit according to the present invention comprises the clock generating circuit for each functional block incorporated therein.

According to such a configuration, it becomes unnecessary to distribute the clock signals because the clock generating circuit is independently provided for each functional block. In short, the clock-series wirings can be reduced. This achieves the control of the clock skews caused by the wiring delays in the wiring distribution.

A third semiconductor integrated circuit according to the present invention comprises the clock generating circuit for each unblocked synchronous circuit cell and for each functional block incorporated therein. This configuration corresponds to the first and second semiconductor integrated circuits combined.

According to such a configuration, it becomes unnecessary to distribute the clock signals because the clock generating circuit is provided for each unblocked synchronous circuit cell and functional block meaning that the clock-series wirings can be reduced or omitted. The clock skews caused by the wiring delays in the wiring distribution can be thereby controlled.

In a fourth semiconductor integrated circuit according to the present invention, any of the first through third semiconductor integrated circuits further comprises, a clock synchronous signal generating circuit, the clock synchronous signal generating circuit periodically generating and outputting the clock synchronous signals with respect to the respective clock generating circuits.

According to such a configuration, the clock synchronous signals are periodically supplied to the respective clock generating circuits by the clock synchronous signal generating circuit so that the clock generating circuits are periodically synchronized. As a result, the clock signals can be periodically phase-combined, and the clock skews can be thereby more effectively controlled.

In a fifth semiconductor integrated circuit according to the present invention, the fourth semiconductor integrated circuit further comprises a phase difference detecting circuit, the phase difference detecting circuit detecting phase differences of the clock signals respectively generated by the clock generating circuits, and the phase difference detecting circuit further activating the clock synchronous generating circuit when the phase differences equal to or exceeding a predetermined value are detected to thereby have the respective clock generating circuits output the clock synchronous signals.

According to such a configuration, the phase differences of the respective clock signals outputted from the plural clock generating circuits are detected by the phase difference detecting circuit. Then, the clock synchronous signal generating circuit is activated whenever the phase differences equal to or exceeding the predetermined value occur among the clock signals so that the clock signals are synchronized. Thus, the expansion of the phase differences can be restricted to stay within a certain range. More specifically, instead of merely synchronizing the clock signals on a periodic basis, the clock signals are forcibly synchronized when the phase differences increase to be more than a certain value. The clock skews can be thereby more effectively controlled. In the present configuration, the clock synchronous generating circuit generates and outputs the clock synchronous signals only in the case in which the phase difference detecting circuit detects the phase differences equal to or exceeding the predetermined value. The phase difference detecting circuit is normally on standby, generating or outputting no clock synchronous signals. Because of that, the power consumption can be reduced.

In a sixth semiconductor integrated circuit according to the present invention, any of the first through third semiconductor integrated circuits further comprises a clock enable signal generating circuit, the clock enable signal generating circuit generating clock enable signals only in the case in which the clock supply is demanded, the clock enable signals generating circuit further supplying the respective clock generating circuits with the clock enable signals to thereby activate the clock generating circuits.

According to such a configuration, the clock enable signals are supplied to only the unblocked synchronous circuit cells or the clock generating circuits linked with the functional blocks, which require the clock supply for operation, in order to activate such. The unblocked synchronous circuit cells or the clock generating circuits linked with the functional blocks, which require no clock supply for operation, are arranged to be in a nonaction state. Therefore, the power consumption can be reduced. Further, the clock signals are synchronized among the clock generating circuits sharing the clock enable signals because of the shared clock enable signals. As a result, the skews of the respective clock signals can be controlled.

A seventh semiconductor integrated circuit according to the present invention comprises, any of the first through third semiconductor integrated circuits comprises the clock enable signal generating circuit, clock synchronous signal generating circuit, and the phase difference detecting circuit having the following capabilities. The clock enable signal generating circuit generates the clock enable signals only in the case in which the clock supply is demanded and further supplies the respective clock generating circuits with the clock enable signals to there by activate the clock generating circuits. The clock synchronous signal generating circuit generates and outputs the clock synchronous signals with respect to the respective clock generating circuits. The phase difference detecting circuit detects the phase differences of the clock signals generated by the respective clock generating circuits and activates the clock synchronous signal generating circuit when the phase differences equal to or exceeding the predetermined value are detected to thereby have the respective clock generating circuits output the clock synchronous signals. This semiconductor integrated circuit corresponds to the fifth and sixth semiconductor integrated circuits combined.

The operation of the semiconductor integrated circuit according to the foregoing configuration is as follows. The clock enable signals are supplied to only the unblocked synchronous circuit cells or the clock generating circuits linked with the functional blocks, which require the clock supply for operation. When the clock enable signals are commonly supplied to the plural clock generating circuits, the clock signals are synchronized among the plural clock generating circuits. Therefore, the skews of the respective clock signals can be controlled.

The phase differences are possibly generated among the respective clock signals outputted from the plural clock generating circuits as the operation is further continued. In such a case, the phase differences among the clock signals are detected by the phase difference detecting circuit, and whenever the phase differences equal to or exceeding the predetermined value occur, the clock synchronous signal generating circuit is activated so that the clock signals are synchronized. Therefore, the skews of the respective clock signals are timely controlled. In the foregoing configuration, the clock synchronous signals are generated and outputted, not on a constant basis, but only in the case in which the phase differences are equal to or exceed the predetermined value. Namely, the clock synchronous signal generating circuit is normally on standby, generating or outputting no clock synchronous signals, thereby resulting in the reduced power consumption.

In an eighth semiconductor integrated circuit according to the present invention, any of the first through third semiconductor integrated circuits is configured in such manner that clock frequencies are variable in the respective clock generating circuits in compliance with voltages applied thereto, and further comprises a supplied voltage adjusting circuit, the supplied voltage adjusting circuit being capable of individually adjusting the voltages applied to the respective clock generating circuits.

According to such a configuration, the higher voltages are supplied from the supplied voltage adjusting circuit to the clock generating circuits linked with the unblocked synchronous circuit cells or functional blocks, which are operated at higher speeds. Thereby, the clock signals generated in the foregoing clock generating circuits can be of the higher frequencies. On the contrary, the lower voltages can be supplied from the supplied voltage adjusting circuit to the clock generating circuits linked with the unblocked synchronous circuit cells or functional blocks, which are operable at lower speeds. Because the frequencies can be individually controlled for the respective clock generating circuit in compliance with the voltages applied thereto, it becomes unnecessary to coordinate the clock frequencies to be suitable to any critical segment, thereby resulting in the lower power consumption.

In a ninth semiconductor integrated circuit according to the present invention, the eight semiconductor integrated circuit further comprises a voltage difference detecting circuit, the voltage difference detecting circuit inputting voltages for destinations of the supplied clock signals generated by the respective clock generating circuits, the voltage difference detecting circuit further detecting differences between the inputted voltages and an ideal voltage to thereby control the supplied voltage adjusting circuit in compliance with the voltage differences.

According to such a configuration, when the voltages for the destinations of the clock signals are relatively low and the voltage difference detecting circuit accordingly detects large voltage differences, the voltages applied by the supplied voltage adjusting circuit and the clock frequencies of the clock generating circuits are set to be higher, which compensates for the low voltages in the destinations. On the contrary, when the voltages for the destinations of the clock signals are relatively high and the voltage difference detecting circuit accordingly detects small voltage differences, the voltages applied by the supplied voltage adjusting circuit and the clock frequencies of the clock generating circuits are set to be lower, which results in the lower power consumption.

The foregoing and other aspects of the invention will become clear by the following description when considered in conjunction with the accompanying drawing figures.

### BRIEF DESCRIPTION OF THE DRAWINGS

FIG. 1 is a view illustrating a configuration of a semiconductor integrated circuit according to Embodiment 1 of the present invention.

FIG. 2 is a view illustrating a configuration of a semiconductor integrated circuit according to Embodiment 2 of the present invention.

FIG. 3 is a view illustrating a configuration of a semiconductor integrated circuit according to Embodiment 3 of the present invention.

FIG. 4 is a view illustrating a configuration of a semiconductor integrated circuit according to Embodiment 4 of the present invention.

FIG. 5 is a view illustrating a configuration of a semiconductor integrated circuit according to Embodiment 5 of the present invention.

FIG. 6 is a view illustrating a configuration of a semiconductor integrated circuit according to Embodiment 6 of the present invention.

FIG. 7 is a view illustrating a configuration of a semiconductor integrated circuit according to Embodiment 7 of the present invention.

FIG. 8 is a view illustrating a configuration of a semiconductor integrated circuit according to Embodiment 8 of the present invention.

FIG. 9 is a view illustrating a configuration of a semiconductor integrated circuit according to Embodiment 9 of the present invention.

In all these figures, like components are indicated by the same numerals

### DETAILED DESCRIPTION

Hereinafter, preferred embodiments of a semiconductor integrated circuit according to the present invention are described in detail referring to the drawings. As a typical example of synchronous circuit cells, flip-flops are cited in this description.

### EMBODIMENT 1

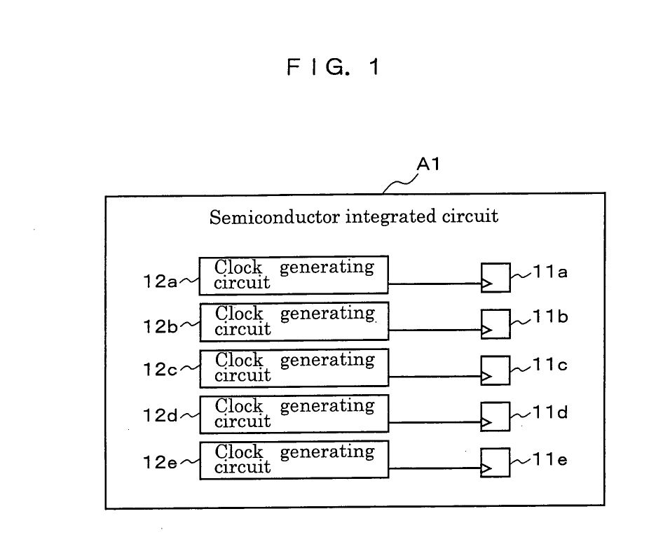

FIG. 1 is a view illustrating a configuration of a semiconductor integrated circuit Al according to Embodiment 1 of the present invention.

As shown in FIG. 1, the semiconductor integrated circuit Al comprises a plurality of flip-flops 11a-11e, to which clock generating circuits 12a-12e of a self-energizing type are individually connected. The clock generating circuits 12a-12e are, for example, each comprised of a ring oscillator with a single or a plurality of inverter circuits connected thereto (this feature is included in any of the following embodiments).

The respective flip-flops 11a-11e are individually supplied with clock signals from the clock generating circuits 12a-12e, to which the flip-flops 11a-11e are respectively connected.

According to the present embodiment, the clock generating circuit is provided for each flip-flop. Therefore, it becomes unnecessary to distribute the clock signals, and clock-series wirings required for the distribution can be accordingly omitted. Clock skews caused by wiring delays in the wiring distribution can be thus controlled.

### EMBODIMENT 2

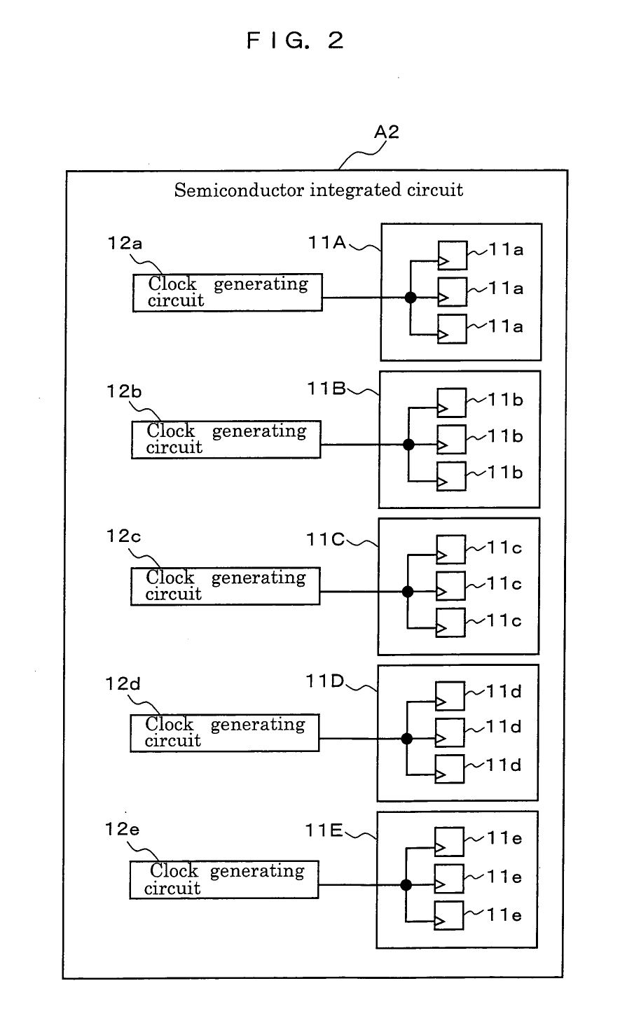

As shown in FIG. 2, in a semiconductor integrated circuit A2 according to Embodiment 2, the flip-flops are divided into blocks. A plurality of flip-flops 11a are blocked into a functional block 11A, and in the same manner, a plurality of flip-flops 11b are blocked into a functional block 11B, a plurality of flip-flops 11c are blocked into a functional block 11C, a plurality of flip-flops 11d are blocked into a functional block 11D and a plurality of flip-flops 11e are blocked into a functional block 11E. The clock generating circuits 12a-12e of the self-energizing type are individually connected to the functional blocks 11A-11E.

According to the present embodiment, each functional block independently comprises the clock generating circuits, which eliminates the need for the distribution of the clock signals and thereby reduces the clock-series wirings for the distribution. The clock skews caused by the wiring delays in the wiring distribution can be thus controlled.

### EMBODIMENT 3

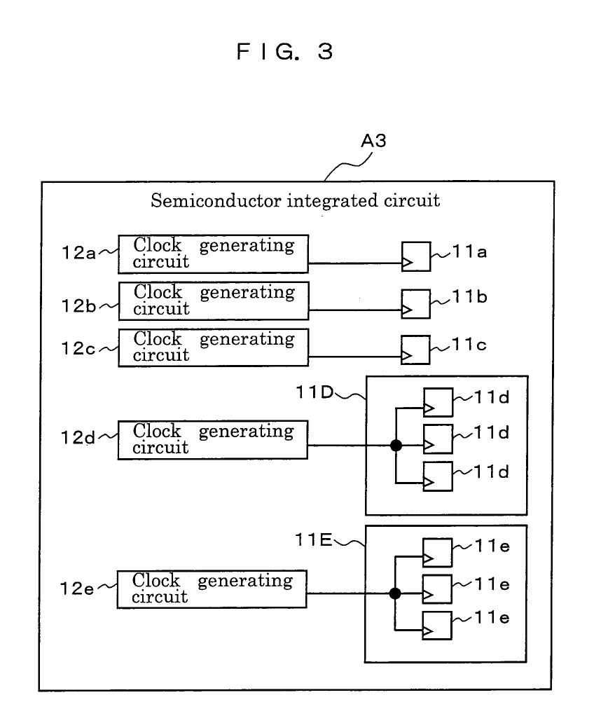

As shown in FIG. 3, in a semiconductor integrated circuit A3 according to Embodiment 3, some flip-flops are divided into blocks, and others remain unblocked. The clock generating circuits 12a, 12b, and 12c are separately connected to the unblocked flip-flops 11a, 11b, and 11c for implementing the clock input thereto. The functional block 11D is comprised of the plural blocked flip-flops 11d, to which the clock generating circuit 12d is connected to be thereby commonly used for the clock input to the respective flip-flops 11d. The functional block 11E is comprised of the plural blocked flip-flops 11e, to which the clock generating circuit 12e is connected to be thereby commonly used for the clock input to the respective flip-flops 11e.

The unblocked flip-flops 11a, 11b, and 11c are individually supplied with the clock signals from the clock generating circuits 12a, 12b, and 12c, to which they are respectively connected. To the plural flip-flops 11d belonging to the functional block 11D are distributed the clock signals from the clock generating circuits 12d, to which they are respectively connected. To the plural flip-flops 11e belonging to the functional block 11E are distributed the clock signals from the clock generating circuits 12e, to which they are respectively connected.

According to the present embodiment, the clock generating circuit is provided for each unblocked flip-flop and functional block. Therefore, the clock-series wirings in order to distribute the clock signals can be omitted or reduced. The clock skews caused by the wiring delays in the wiring distribution can be thus controlled.

### EMBODIMENT 4

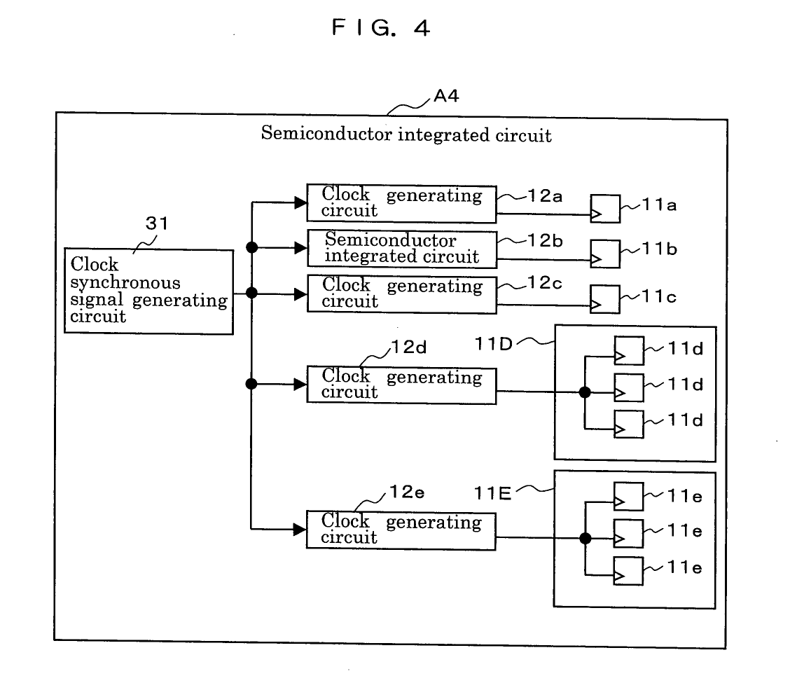

In FIG. 4, the reference numerals identical to those in FIG. 3 refer to the same components.

In a semiconductor integrated circuit A4 according to Embodiment 4, the plural clock generating circuits 12a-12e, plural flip-flops 11a-11e, and plural functional blocks 11D and 11E are related to one another in the same manner as in the case of FIG. 3. In the present embodiment, a clock synchronous signal generating circuit 31, which periodically generates and outputs the clock synchronous signals, is included. The plural clock generating circuits 12a-12e are synchronously controlled by means of the clock synchronous signals outputted from the clock synchronous signal generating circuit 31 so that the clock signals outputted from the clock generating circuits 12a-12e are periodically synchronized. The description of the rest of the entire configuration, which is the same as in the Embodiment 3, is omitted.

According to the present embodiment, because the clock synchronous signals from the clock synchronous signal generating circuit are periodically supplied to all the clock generating circuits, the clock signals generated by the clock generating circuits can be periodically synchronized. More specifically, the clock signals supplied to the unblocked flip-flops and the respective flip-flops of the functional blocks can be periodically phase-combined. This enables the control of the clock skews to be more effective.

### EMBODIMENT 5

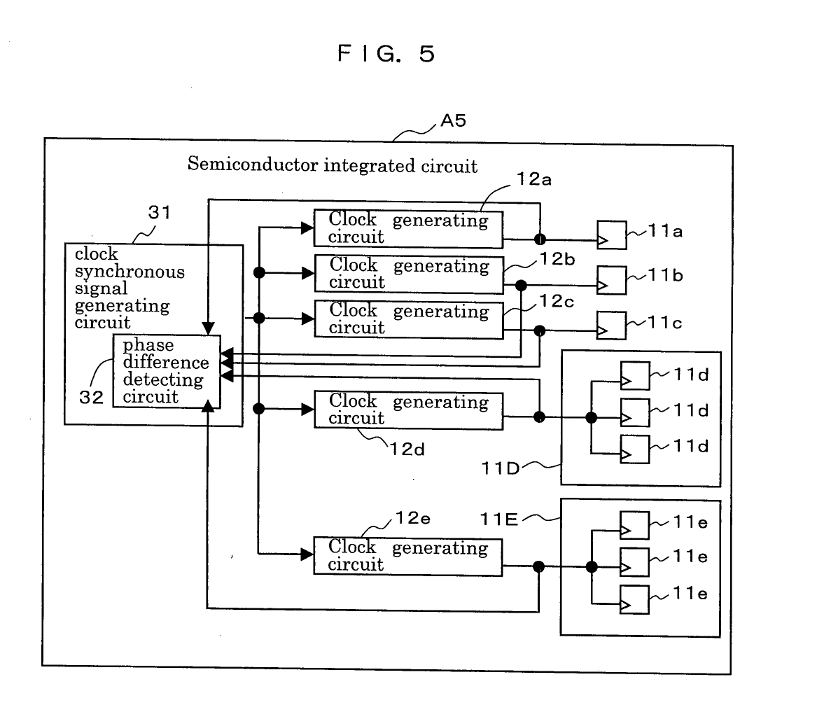

In FIG. 5, the reference numerals identical to those in FIG. 4 refer to the same components.

In a semiconductor integrated circuit A5 according to Embodiment 5, the plural clock generating circuits 12a-12e, plural flip-flops 11a-11e, plural functional blocks 11D and 11E, and clock synchronous signal generating circuit 31 are related to one another in the same manner as in the case of FIG. 4. According to the present embodiment, the clock synchronous signal generating circuit 31 includes a phase difference detecting circuit 32. The phase difference detecting circuit 32 inputs the clock signals from all the clock generating circuits 12a-12e thereto and detects the phase differences among the clock signals. When the phase difference detecting circuit 32 detects the phase differences equal to or exceeding the predetermined value possibly leading to any malfunction, the clock synchronous signal generating circuit 31 outputs the clock synchronous signals to the respective clock generating circuits 12a-12e. The description of the rest of the entire configuration, which is the same as in the Embodiment 4, is omitted.

When the phase differences are occurring among the clock signals outputted from the clock generating circuits 12a-12e to the extent that the semiconductor integrated circuit A5 possibly undergoes any malfunction, the phase difference detecting circuit 32 detects the state. The phase difference detecting circuit 32 then activates the clock synchronous signal generating circuit 31 and outputs the clock synchronous signals to the respective clock generating circuits 12a-12e. The clock signals from all the clock generating circuits 12a-12e are thereby synchronized.

According to the present embodiment, the phase difference detecting circuit, which detects the phase differences among the respective clock signals outputted from the plural clock generating circuits, is included so that the clock signals can be forcibly synchronized whenever the phase differences equal to or exceeding the predetermined value occur among the clock signals. More specifically, instead of merely synchronizing the clock signals on a periodic basis, the clock signals are forcibly synchronized whenever the phase differences exceed the predetermined level. In this manner, the clock skews can be more effectively controlled. In the present configuration, the clock synchronous signals are generated and outputted by the clock synchronous generating circuit only in the case in which the phase difference detecting circuit detects the phase differences equal to or exceeding the predetermined value. The clock synchronous generating circuit is normally on standby, generating and outputting no clock synchronous signals. This achieves the reduction of the power consumption.

### EMBODIMENT 6

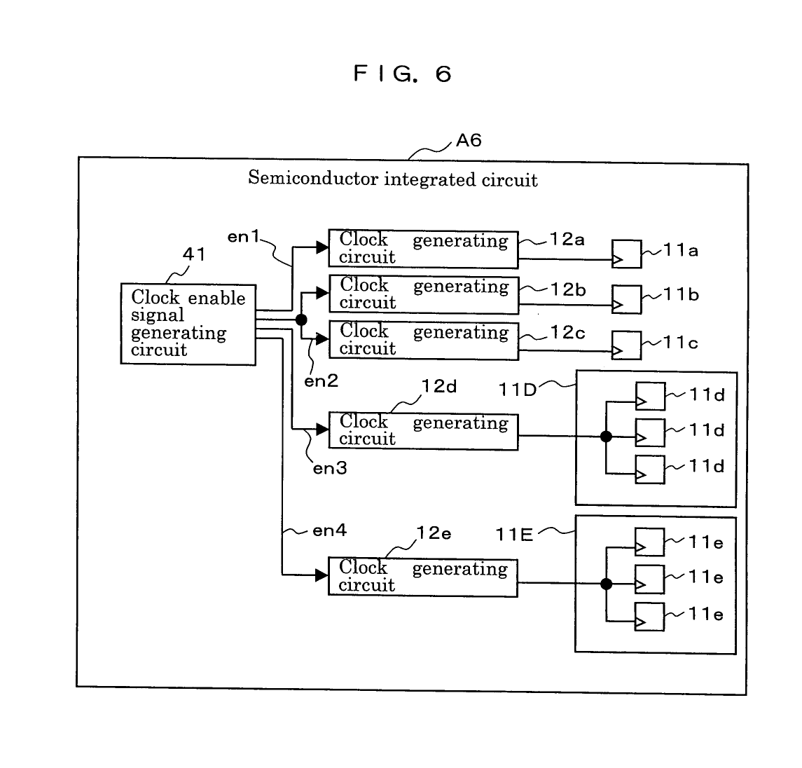

In FIG. 6, the reference numerals identical to those in FIG. 3 refer to the same components. In a semiconductor integrated circuit A6 according to Embodiment 4, the plural clock generating circuits 12a-12e, plural flip-flops 11a-11e, and plural functional blocks 11D and 11E are related to one another in the same manner as in the case of FIG. 3. According to the present embodiment, a clock enable signal generating circuit 41 is provided. Clock enable signals en1-en4 are independently supplied to the respective clock generating circuits 12a-12e from the clock enable signal generating circuit 41. In the case of an example shown in FIG. 6, the clock enable signal en2 is commonly supplied to the clock generating circuits 12b and 12c. The clock generating circuit 12a is activated only in the case in which the clock enable signal en1 is effective and outputs the clock signals. The clock generating circuits 12b and 12c is activated only in the case in which the clock enable signal en2 is effective and outputs the clock signals. The clock generating circuit 12d is activated only in the case in which the clock enable signal en3 is effective and outputs the clock signals. The clock generating circuit 12e is activated only in the case in which the clock enable signal en4 is effective and outputs the clock signals. The description of the rest of the entire configuration, which is the same as in the Embodiment 3, is omitted.

The clock enable signals en1-en4 are changed to a higher level only in the case in which the flip-flops corresponding thereto must be operated, and separately controllable.

For example, when the clock enable signals en1-en4 are all set at “1”, the clock generating circuits 12a-12e supply the unblocked flip-flops 11a, 11b and 11c, and the flip-flops 11d and 11e of the functional blocks 11D and 11E with the clock signals.

As another example, when the clock enable signals en1-en4 are all reset at “0”, the clock generating circuits 12a-12e terminate the supply of the clock signals with respect to the unblocked flip-flops 11a, 11b and 11c, and the flip-flops 11d and 11e of the functional blocks 11D and 11E.

As yet another example, when the clock generating circuits 12a and 12d supply the clock signals and the clock generating circuits 12b, 12c and 12e terminate the clock supply, the clock enable signals en1 and en3 are set at “1”, and the clock enable signals en2 and en4 are reset at “0”.

Referring to the case in which the clock enable signals en1-en4 are set at “1”, and the clock signals are thereby ready to be supplied to the unblocked flip-flops 11a, 11b and 11c and the flip-flops 11d and 11e of the functional blocks 11D and 11E from the clock generating circuits 12a-12e, the clock enable signal generating circuit 41 sets the clock enable signals en1-en4 at “1” in synchronization with an ideal rise timing of the clock signals.

The configuration according to the present embodiment comprises the clock enable generating circuit, which generates the clock enable signals becoming effective only in the case in which the clock supply is necessary. In this manner, the clock supply can be terminated with respect to the flip-flops or functional blocks when the clock supply is not necessary, and the reduction of the power consumption is thereby achieved. In addition, the clock signals are synchronized in the clock generating circuits sharing the clock enable signals. As a result, the skews of the respective clock signals can be appropriately controlled so that the clock-delay-caused malfunctions can be prevented from occurring.

### EMBODIMENT 7

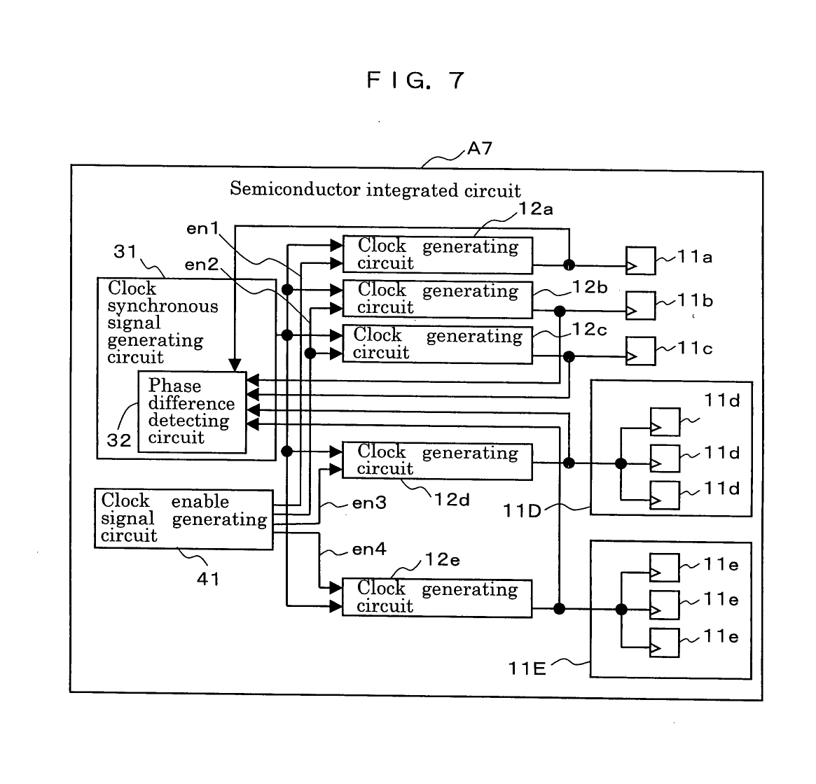

In FIG. 7, the reference numerals identical to those in FIGS. 5 and 6 refer to the same components. A semiconductor integrated circuit A7 according to Embodiment 7 corresponds to the combination of the configurations according to the Embodiments 5 and 6. In other words, the clock synchronous signal generating circuit 31, phase difference detecting circuit 32, and clock enable signal generating circuit 41 are included. The description of the rest of the entire configuration, which is the same as in the Embodiments 5 and 6, is omitted.

According to the present embodiment, the clock enable signal generating circuit, which generates the clock enable signals becoming effective only in the case in which the clock supply is necessary. Accordingly, the clock supply with respect to the flip-flops or functional blocks can be terminated when the clock supply is not demanded, and the power consumption can be thereby reduced. Moreover, the clock signals are synchronized in the clock generating circuits sharing the clock enable signals. As a result, the skews of the respective clock signals are appropriately controlled, and the clock-delay-caused malfunctions can be prevented from occurring.

Further, the phase difference detecting circuit, which detects the phase differences of the respective clock signals outputted from the plural clock generating circuits, is comprised. In this configuration, the clock signals can be forcibly synchronized whenever the phase differences equal to or exceeding the predetermined value occur among the clock signals. The skews of the respective clock signals can be thereby appropriately controlled. The clock synchronous signal generating circuit generates and outputs the clock synchronous signals only in the case in which the phase difference detecting circuit detects the phase differences equal to or exceeding the predetermined value. The clock synchronous signal generating circuit is normally on standby, generating and outputting no clock synchronous signals, which results in the reduction of the power consumption.

### EMBODIMENT 8

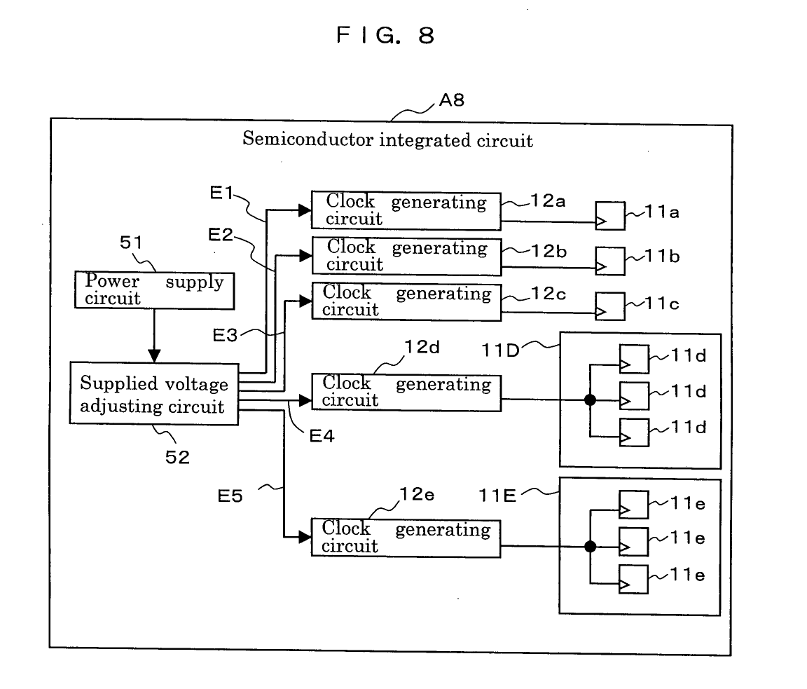

In FIG. 8, the reference numerals identical to those in FIG. 3 refer to the same components. In a semiconductor integrated circuit A8 according to Embodiment 8, the plural clock generating circuits 12a-12e, plural flip-flops 11a-11e, and plural functional blocks 11D and 11E are related to one another in the same manner as in the case of FIG. 3. In the present embodiment, the respective clock generating circuits 12a-12e have a configuration of a VCO type capable of adjusting oscillatory frequencies in compliance with voltages applied thereto, and a supplied voltage adjusting circuit 52 is provided between the clock generating circuits 12a-12e and a power supply circuit 51 which supplies the respective clock generating circuits 12a-12e. with power, the supplied voltage adjusting circuit 52 being capable of separately adjusting voltages E1-E5 applied to the respective clock generating circuits 12a-12e. The description of the rest of the entire configuration, which is the same as in the Embodiment 3, is omitted.

The supplied voltage adjusting circuit 52 separately adjusts the voltages E1-E5 applied to the clock generating circuits 12a-12e. The clock generating circuits 12a-12e adjust the clock frequencies in compliance with the applied voltages E1-E5 supplied by the supplied voltage adjusting circuit 52.

When the clock signals of the high frequencies are supplied to any of the unblocked flip-flops 11a, 11b and 11c, and the flip-flops 11d and 11e of the functional blocks D and E, the supplied voltage adjusting circuit 52 arranges the applied voltages with respect to the clock generating circuits to be of higher potentials. As a result, the flip-flops can be supplied with the clock signals of the higher frequencies.

On the contrary, when the clock signals of the lower frequencies are supplied to the flip-flops, the supplied voltage adjusting circuit 52 arranges the applied voltages with respect to the clock generating circuits to be of lower potentials. As a result, the flip-flops can be supplied with the clock signals of the lower frequencies.

For example, when the clock signals of the frequency higher than that of the clock signals from the clock generating circuit 12b are requested as the clock signals to be supplied from the clock generating circuit 12a, the applied voltage E1 with respect to the clock generating circuit 12a is set to be higher than the applied voltage E2 with respect to the clock generating circuit 12b.

The configuration according to the present embodiment comprises the supplied voltage adjusting circuit capable of separately adjusting the applied voltages in compliance with the requested clock frequencies. Accordingly, the frequencies of the clock signals generated by the clock generating circuits can be independently controlled. As a result, it become unnecessary to coordinate the clock frequencies to be suitable to any critical segment, the lower power consumption can be successfully achieved.

### EMBODIMENT 9

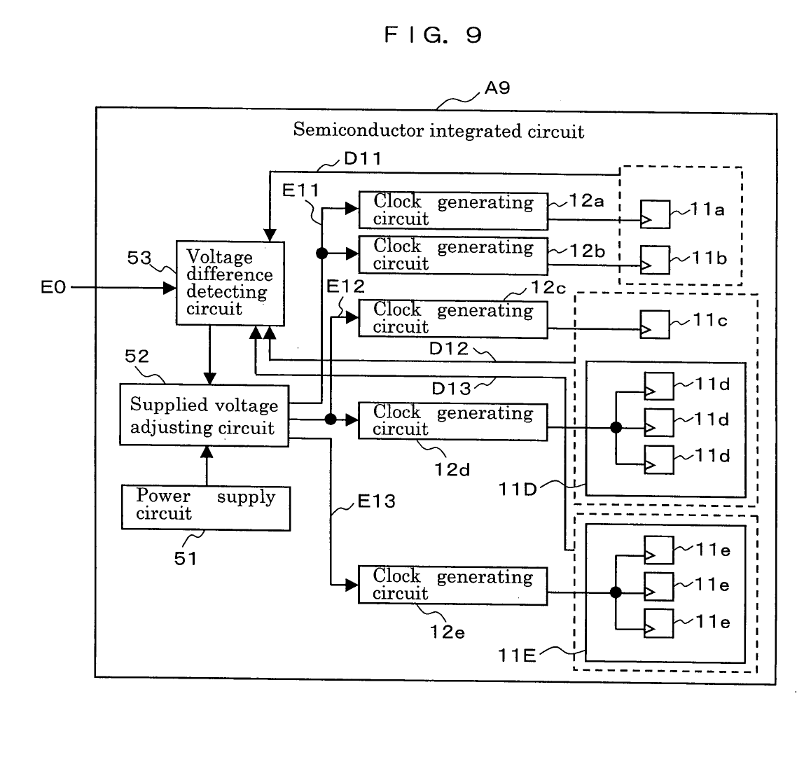

In FIG. 9, the reference numerals identical to those in FIG. 8 refer to the same components.

In a semiconductor integrated circuit A9 according to Embodiment 9, the plural clock generating circuits 12a-12e, plural flip-flops 11a-11e, plural functional blocks 11D and 11E, power supply circuit 51, and supplied voltage adjusting circuit 52 are related to one another in the same manner as in the case of FIG. 8. In the case of an example shown in FIG. 9, the applied voltage E11 is commonly supplied to the clock generating circuits 12a and 12b from the supplied voltage adjusting circuit 52, the applied voltage E12 is commonly supplied to the clock generating circuits 12c and 12d from the supplied voltage adjusting circuit 52, the applied voltage E13 is commonly supplied to the clock generating circuit 12e from the supplied voltage adjusting circuit 52. In the present embodiment, a voltage difference detecting circuit 53 is provided, the voltage difference detecting circuit 53 inputting power voltages D11, D12 and D13 for the respective segments of the semiconductor integrated circuit A9 and further detecting the voltage differences between the inputted voltages and an ideal voltage V0. The supplied voltage adjusting circuit 52 is controlled in accordance with the voltage differences, and the applied voltages E11, E12 and E13 with respect to the clock generating circuits 12a-12e are thereby adjusted. The description of the rest of the entire configuration, which is the same as in the Embodiment 8, is omitted.

For example, the applied voltage E11 from the supplied voltage adjusting circuit 52 with respect to the clock generating circuits 12a and 12b is determined according to a voltage difference ΔE (=D11-E0) between the power voltage D11 in the segment where the unblocked flip-flops 11a and 11b are present and the ideal voltage E0. The clock generating circuits 12a and 12b generate and output the clock signals of the frequency determined according to the applied voltage E11.

Further, the applied voltage E12 from the supplied voltage adjusting circuit 52 with respect to the clock generating circuits 12c and 12d is determined according to the voltage difference ΔE (=D12−E0) between the power voltage D12 in the segment where the unblocked flip-flop 11c and the functional block 11D are present and the ideal voltage E0. The clock generating circuits 12c and 12d generate and output the clock signals of the frequency determined according to the applied voltage E12.

Further, the applied voltage E13 from the supplied voltage adjusting circuit 52 with respect to the clock generating circuit 12e is determined according to the voltage difference ΔE (=D13-E0) between the power voltage D12 in the segment where the functional block 11E is present and the ideal voltage E0. The clock generating circuit 12e generates and outputs the clock signals of the frequency determined according to the applied voltage E11.

The configuration according to the present embodiment employs the power supply circuit including the voltage difference detecting circuit and the supplied voltage adjusting circuit, the applied voltages of which being controlled by the power supply circuit. The supplied voltage adjusting circuit is controlled in accordance with the changing voltages in the semiconductor integrated circuit so that the frequencies of the clock signals generated by the clock generating circuits can be controlled. This achieves the reduced power consumption of the semiconductor integrated circuit.

As thus far described, according to the present invention, the clock generating circuit is provided for each synchronous circuit cell or functional block. This configuration dispenses with the distribution of the clock signals and can thereby eliminate or reduce the clock-series wirings for the distribution. Accordingly, the clock skews caused by the wiring delays in the wiring distribution can be controlled, and the power consumption can be reduced.

What is claimed is:

1. A semiconductor integrated circuit comprising:
a plurality of synchronous circuit cells; and
a plurality of clock generating circuits individually connected to the plurality of synchronous circuit cells.

2. A semiconductor integrated circuit comprising:
a plurality of functional blocks each having a plurality of synchronous circuit cells incorporated therein; and
a plurality of clock generating circuits individually connected to the plurality of functional blocks.

3. A semiconductor integrated circuit comprising:
a plurality of unblocked synchronous circuit cells;
a plurality of functional blocks each having a plurality of synchronous circuit cells incorporated therein; and
a plurality of clock generating circuits individually connected to the plurality of synchronous circuit cells and the plurality of functional blocks.

4. A semiconductor integrated circuit as claimed in any of claims 1 through 3, wherein
a clock synchronous signal generating circuit is further comprised,
the clock synchronous signal generating circuit periodically generating and outputting clock synchronous signals with respect to the respective clock generating circuits.

5. A semiconductor integrated circuit as claimed in claim 4, wherein
a phase difference detecting circuit is further comprised,
the phase difference detecting circuit detecting phase differences among the respective clock signals generated by the respective clock generating circuits, and
the phase difference detecting circuit further activating the clock synchronous signal generating circuit when the phase differences equal to or exceeding a predetermined value are detected to thereby have the respective clock generating circuits output the clock synchronous signals.

6. A semiconductor integrated circuit as claimed in any of claims 1 through 3, wherein
a clock enable signal generating circuit is further comprised,
the clock enable signal generating circuit generating clock enable signals only in the case in which a clock supply is demanded, and
the clock enable signal generating circuit further supplying the respective clock generating circuits with the clock enable signals to thereby activate the respective clock generating circuits.

7. A semiconductor integrated circuit as claimed in any of claims 1 through 3 further comprising:
a clock enable signal generating circuit,
the clock enable signal generating circuit generating clock enable signals only in the case in which a clock supply is demanded, and
the clock enable signal generating circuit further supplying the respective clock generating circuits with the clock enable signals to thereby activate the respective clock generating circuits;
a clock synchronous signal generating circuit,
the clock synchronous signal generating circuit generating and outputting clock synchronous signals with respect to the respective clock generating circuits; and
a phase difference detecting circuit,
the phase difference detecting circuit detecting phase differences among the respective clock signals generated by the respective clock generating circuits, and
the phase difference detecting circuit further activating the clock synchronous signal generating circuit when the phase differences equal to or exceeding a predetermined value are detected to thereby have the respective clock generating circuits output the clock synchronous signals.

8. A semiconductor integrated circuit as claimed in any of claims 1 through 3, wherein
the clock generating circuits are configured in such manner that clock frequencies are variable in compliance with voltages applied thereto, and
a supplied voltage adjusting circuit is further comprised,
the supplied voltage adjusting circuit being capable of separately adjusting the voltages applied to the respective clock generating circuits.

9. A semiconductor integrated circuit as claimed claim 8, wherein
a voltage difference detecting circuit is further comprised,
the voltage difference detecting circuit inputting thereto voltages for destinations of the clock signals supplied from the respective clock generating circuits, and
the voltage difference detecting circuit further detecting voltage differences between the inputted voltages and an ideal voltage to control the supplied voltage adjusting circuit in accordance with the voltage differences.

10. A semiconductor integrated circuit as claimed in any of claims 1 through 3, wherein
the clock generating circuits have a configuration of a self-energizing type.
